(19) United States
(12) Patent Application Publication
(10) Pub. No.: US 2013/0170144 A1
(43) Pub. Date: Jul. 4, 2013

(54) ELECTRONIC DEVICE WITH HEAT SINK MECHANSIM

(71) Applicant: HONG LI, Shenzhen City (CN)

(72) Inventor: HONG LI, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/600,217

(22) Filed: Aug. 31, 2012

(30) Foreign Application Priority Data
Dec. 30, 2011 (CN) 201110452456.8

(51) Int. Cl. H05K 7/20

(52) U.S. Cl. 361/709

(57) ABSTRACT

An electronic device includes an electronic component and a heat sink mechanism. The electronic component includes at least one heat sink portion defining a plurality of heat sink holes. The heat sink mechanism includes at least one first conducting portion secured to an end of the heat sink holes, for dissipating heat produced by the electronic component away from the electronic device.

### BACKGROUND

1. Technical Field

The present disclosure relates to an electronic device having a heat sink mechanism.

2. Description of Related Art

Electronic devices, such as disc players and notebook computers, include electronic components, which generate heat while in use. This generated heat increases the temperature of the electronic components. Because some components of an electronic device has a maximum operating temperature, if an electronic component is operated at a temperature exceeding the maximum operating temperature, its lifespan will be shortened and the electronic devices may be damaged.

Therefore, there is room for improvement in the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an isometric view of an embodiment of an electronic device.

FIG. 2 is a partial, disassembly view of the electronic device of FIG. 1.

FIG. 3 is an enlarged view of portion II of FIG. 2.

FIG. 4 is a partial, assembly view of the electronic device of FIG. 2.

### DETAILED DESCRIPTION

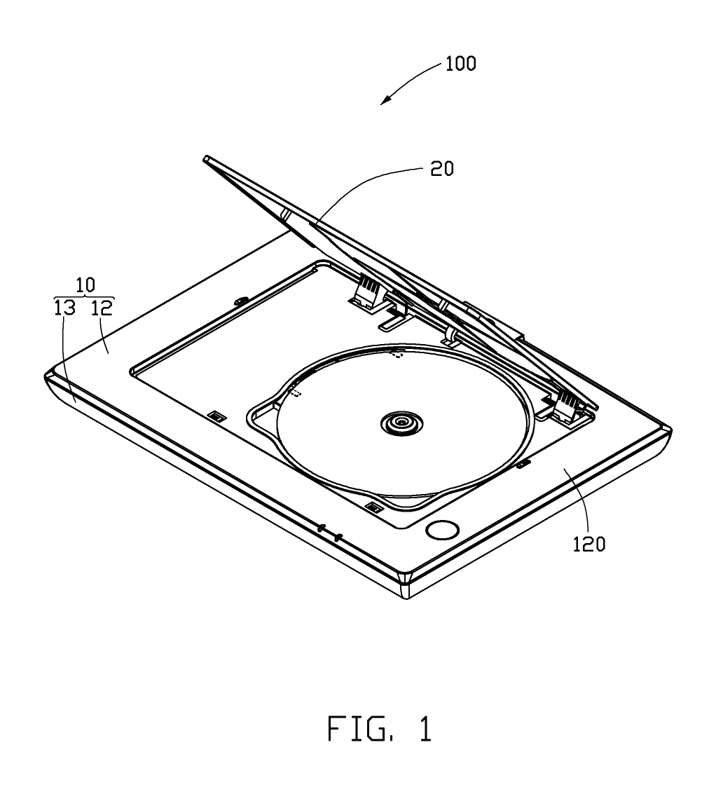

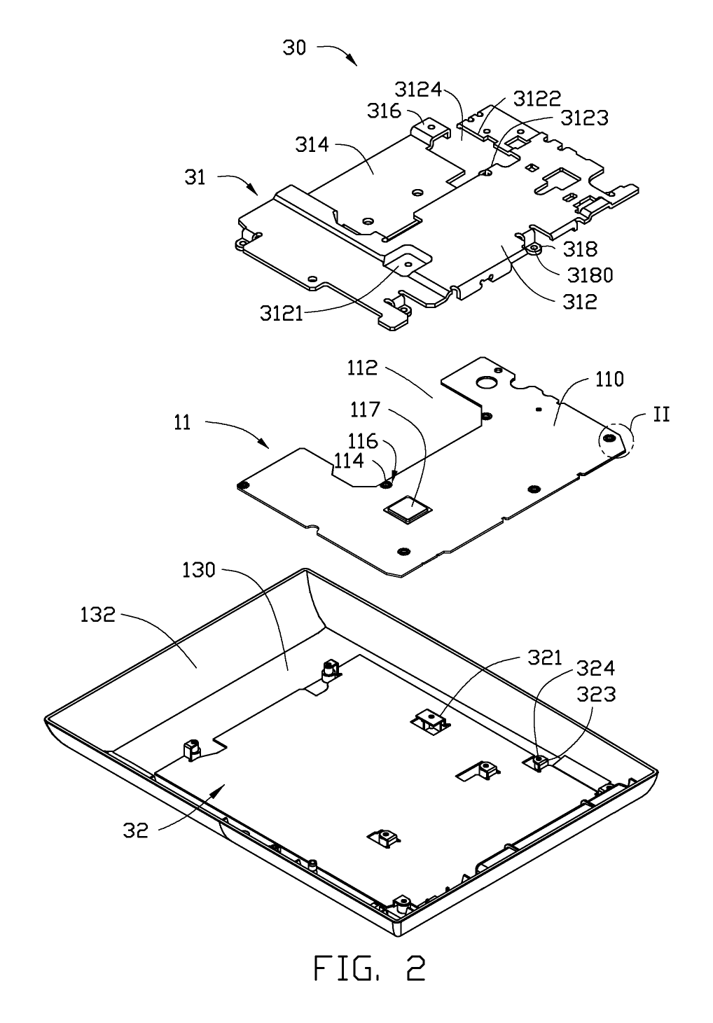

Referring to FIGS. 1 and 2, an embodiment of an electronic device 100 is illustrated. The electronic device 100 includes a base 10, an electronic component 11, a cover 20 rotatably connected to the base 10, and a heat sink mechanism 30. The base 10 includes a top case 12 having a top plate 120 and a bottom case 13 connected to the top case 12. The bottom case 13 includes a bottom plate 130 opposite to the top plate 120 and four sidewalls 132 extending from rims of the bottom plate 130. The top case 12 cooperates with the bottom case 13 to define a receiving space (not labeled), for receiving the electronic component 11, the heat sink mechanism 30, and other components. The heat sink mechanism 30 is used for dissipating heat produced by the electronic component 11. The electronic device 100 may be a notebook computer, a disc player, or other electronic devices. In the embodiment, the electronic device 100 is a disc player.

The electronic component 11 is substantially plate-shaped, and includes a first surface 110, a second surface (not shown) opposite to the first surface 110, a plurality of heat sink portions 116, and a heat-producing component 117. The heat-producing component 117 protrudes out of the first surface 110. The heat-producing component 117 may be an integrated circuit (IC) chip or other heat-producing components. In the embodiment, the heat-producing component 117 is an IC chip. The electronic component 11 defines a substantially U-shaped opening 112.

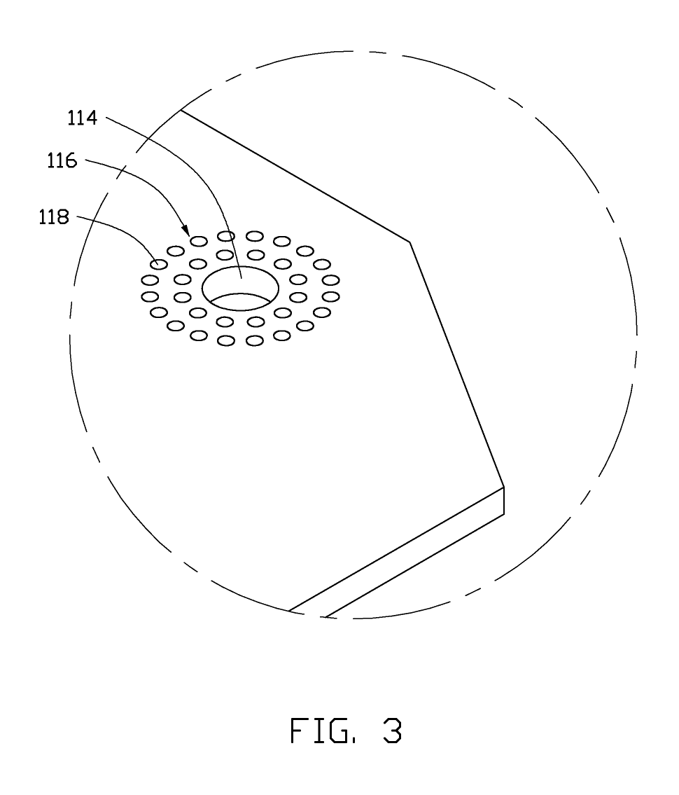

Referring also to FIG. 3, the heat sink portions 116 are arranged around the edge of the electronic component 11 and are spaced from each other. Each heat sink portion 116 defines a central hole 114 and a plurality of circular-shaped heat sink holes 118. The heat sink holes 118 encircle the central hole 114. The inner surface of each central hole 114 is electrically conductive. The first surface 110 and the second surface are covered by an insulation layer except where the heat sink portions 116 are positioned. The shape and the manner of the heat sink holes 118 encircling the central hole 114 may be changed according to need.

Referring to FIG. 2 again, the heat sink mechanism 30 of the embodiment is shown. The heat sink mechanism 30 includes a first plate-shaped heat sink component 31 and a second plate-shaped heat sink component 32 engaging with the first heat sink component 31. The first heat sink component 31 and the second heat sink component 32 are arranged on opposite surfaces of the electronic component 11. In the embodiment, the second heat sink component 32 is mounted on the bottom plate 130, the electronic component 11 is arranged on the second heat sink component 32, and the first heat sink component 31 is mounted on a surface of the electronic component 11 opposite to the second heat sink component 32. In the embodiment, the first heat sink component 31 and the second heat sink component 32 are made of aluminum.

The first heat sink component 31 is secured to the first surface 110 of the electronic component 11, and includes a first heat transferring portion 312, a second heat transferring portion 314 extending from the first heat transferring portion 312, a first connecting portion 316 and a plurality of spaced first conducting portions 318.

The first heat transferring portion 312 defines a substantially U-shaped recess 3124 corresponding to the opening 112 of the electronic component 11. The recess 3124 includes two opposite first sidewalls 3122 and a second sidewall 3123 connecting with the two first sidewalls 3122. The first heat transferring portion 312 is recessed toward the electronic component 11 to form a concave portion 3121 corresponding to the heat-producing component 117.

The second heat transferring portion 314 corresponds to and is received in the recess 3124. The second heat transferring portion 314 connects with the second sidewall 3123 and one of the first sidewalls 3122. The second heat transferring portion 314 is parallel to the first heat transferring portion 312. When viewed from a top surface of the first heat transferring portion 312 opposite to the electronic component 11, the second heat transferring portion 314 is recessed in the first heat transferring portion 312. When viewed from a bottom surface of the first heat transferring portion 312 opposite to the top surface, the second heat transferring portion 314 protrudes out of the first heat transferring portion 312.

The first connecting portion 316 extends from a side of the second heat transferring portion 314 adjacent to one of the first edges 3122, and protrudes out of a surface of the second heat transferring portion 314 opposite to the second heat sink component 32. The first connecting portion 316 in the embodiment is substantially coplanar with the first heat transferring portion 312.

The first conducting portions 318 are arranged around the edge of the first heat transferring portion 312 and correspond respectively to the heat sink portions 116. The first conducting portions 318 are curved from the edges of the first heat transferring portion 312 and toward the electronic component 11, with the free ends extending in a direction parallel to the first heat transferring portion 312. The size of the free ends of the first conducting portions 318 is substantially equal to that of the corresponding heat sink portion 116, for wholly covering the corresponding heat sink portion 116. Each first conducting portion 318 defines a first through hole 3180. In the embodiment, the second heat transferring portion 314, the concave portion 3121, and the first conducting portions 318 are recessed in the same direction relative to the first heat transferring portion 312. The vertical height of the second heat transferring portion 314 relative to the first heat transferring portion 312 is substantially equal to the distance between the heat-producing component 117 and a surface of the second heat sink component 32 opposite to the electronic component 11. Furthermore, the distance between the first conducting portions 318 and the first heat transferring portion 312 is larger than the distance of the concave portion 3121 and the first heat transferring portion 312.

The second heat sink component 32 is arranged between the bottom plate 130 and the electronic component 11. A second connecting portion 321 and a plurality of spaced second conducting portions 323 are formed on the second heat sink component 32. The second connecting portion 321 corresponds to the first connecting portion 316, for engaging with the first connecting portion 316 to fix the first heat sink component 31 with the second heat sink component 32. Each second conducting portion 323 defines a second through hole 324. The shape of the second conducting portions 323 corresponds to and engages with the first conducting portions 318 respectively. In the embodiment, the area of the second conduction component 32 is larger than the area of the second heat transferring portion 314.

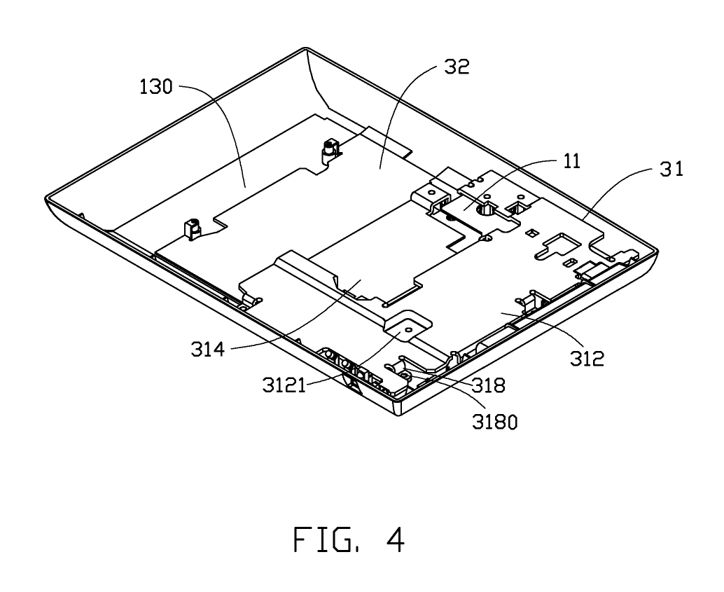

Referring to FIG. 4, in assembly, the second heat sink component 32 is mounted on the bottom plate 130, with the second fixing portion 321 and the second conducting portions 323 toward the top plate 120. The electronic component 11 is mounted on the second heat sink component 32, with the heat-producing component 117 opposite to the second heat sink component 32. The second conducting portions 323 are secured to a surface of the heat sink portions 116, with the second through holes 324 being aligned with the central holes 114 respectively. The first heat sink component 31 is mounted on the first surface 110 of the electronic component 11, with the concave portion 3121 securing and corresponding to the heat-producing component 117. The free ends of the first conducting portions 318 are wholly covered on a surface of the heat sink portions 116 opposite to the first heat sink component 31, with the first through holes 3180 aligned with the central holes 114 respectively. A plurality of fixing members (such as screws, not shown) extend through the first through holes 3180, the central holes 114 and are further secured to the second through holes 323, for fixing the first heat sink component 31, the electronic component 11 and the second heat sink component 32 together.

In this state, the first heat sink component 31, the electronic component 11 and the second heat sink component 32 are kept a predetermined gap with each other. The first heat transferring portion 312 contacts with the heat-producing component 117. The second heat transferring portion 314 extends through the opening 112 and contacts with the second heat sink component 32. The first and second conducting portion 318, 323 are secured on opposite surfaces of the heat sink portions 116.

In use, the heat produced by the heat-producing component 117 is transmitted to the first heat sink component 31. And then, the first heat sink component 31 transmits the heat to the second heat sink component 32 via the second heat transferring portion 314, for dissipating the heat and further transmitting the heat out of the electronic device 100. Simultaneously, the electronic component 11 is surrounded by the first and second heat sink components 31, 32. The first conducting portions 318 and the second conducting portions 323 are secured to opposite surfaces of the heat sink portions 116, thus, the heat from the electronic component 11 is transmitted to the first and second sink components 31, 32 via the heat sink holes 118. Furthermore, the first and second conducting portions 318, 323 electrically contact the electronic component 11, thus, static electricity of the electronic component 11 can be dissipated to ground.

Although information and the advantages of the present embodiments have been set forth in the foregoing description, together with details of the structures and functions of the present embodiments, the disclosure is illustrative only; changes may be made in detail, especially in the matters of shape, size, and arrangement of parts within the principles of the present embodiments to the full extent indicated by the broad general meaning of the terms in which the appended claims are expressed.

What is claimed is:

1. An electronic device comprising:
an electronic component comprising at least one heat sink portion defined a plurality of heat sink holes; and
a heat sink mechanism for dissipating heat generated by the electronic component;
wherein the heat sink mechanism comprises at least one first conducting portion secured to an end of the heat sink holes, for dissipating the heat produced by the electronic component away from the electronic device.

2. The electronic device as claimed in claim 2, wherein the heat sink mechanism comprises a first heat sink component arranged on a surface of the electronic component, the at least one first conducting portion extends from the first heat sink component, for securing the first heat sink component to the electronic component.

3. The electronic device as claimed in claim 2, wherein the heat sink mechanism comprises a second heat sink component arranged on a surface opposite to the first heat sink component of the electronic component; the second heat sink component comprises at least one second conducting portion, the second conduction portion secured to an end opposite to the at least one first conducting portion of the heat sink holes.

4. The electronic device as claimed in claim 3, wherein the at least one first conducting portion protrudes out of the first heat sink component, and the at least one second conducting portion protrudes out of the second heat sink component, for allowing the first heat sink component, the second heat sink component and the electronic component to keep a predetermined gap with each other.

5. The electronic device as claimed in claim 3, wherein the first heat sink component comprises a first heat transferring portion and a second heat transferring portion extended from the first heat transferring portion, the first heat transferring portion is secured to the electronic component, and the second heat transferring portion is secured to the second heat sink component.

6. The electronic device as claimed in claim 5, wherein the first heat sink component defines an open end, the second heat transferring portion extends from a sidewall of the open end; the electronic component defines an opening corresponding to the open end, the second heat transferring portion extends through the opening and is secured to the second heat sink component.

7. The electronic device as claimed in claim 5, wherein the electronic component comprises a first surface and a heat-producing component protruding out of the first surface, the first heat sink component is secured to the first surface and comprises a concave portion secured to the heat-producing component.

8. The electronic device as claimed in claim 7, wherein the vertical height of the second heat transferring portion relative to the first heat transferring portion is substantially equal to the distance between the heat-producing component and a surface of the second heat sink component opposite to the electronic component.

9. The electronic device as claimed in claim 3, wherein each heat sink portion defines a central hole, the heat sink holes encircle the corresponding central hole.

10. The electronic device as claimed in claim 9, wherein the at least one first conducting portion defines a first through hole, and the at least one second conducting portion defines a second through hole; the first and second through holes correspond to the corresponding central hole for fixing the first and second heat sink component to the electronic component.

11. The electronic device as claimed in claim 9, wherein the inner surface of the at least one central hole is an electrical conducting surface for allowing static electricity of the electronic component to be conducted to ground.

12. The electronic device as claimed in claim 3, wherein the first and second heat sink components are made of aluminum.
